(19) United States
(12) Patent Application Publication
(10) Pub. No.: US 2015/0054101 A1
(43) Pub. Date: Feb. 26, 2015

(54) MICROMECHANICAL COMPONENT AND METHOD FOR MANUFACTURING A MICROMECHANICAL COMPONENT

(71) Applicant: Jochen REINMUTH, Reutlingen (DE)

(72) Inventor: Jochen REINMUTH, Reutlingen (DE)

(73) Assignee: Robert Bosch GmbH, Stuttgart (DE)

(21) Appl. No.: 14/467,726

(22) Filed: Aug. 25, 2014

(30) Foreign Application Priority Data
Aug. 26, 2013 (DE) 10 2013 216 901.9

(51) Int. Cl. B81B 3/00; B81C 1/00

(52) U.S. Cl. CPC B81B 3/0078; B81C 1/00825
USPC 257/420; 438/51

(57) ABSTRACT

A micromechanical component comprising a substrate having a main plane of extension, comprising a movable element, and comprising a spring arrangement assemblage is provided, the movable element being attached to the substrate by way of the spring arrangement assemblage, the movable element being deflectable out of a rest position into a deflection position, the movable element encompassing a first sub-element and a second sub-element connected to the first sub-element, the first sub-element extending mainly along the main plane of extension of the substrate, the second sub-element extending mainly along a functional plane, the functional plane being disposed substantially parallel to the main plane of extension of the substrate, the functional plane being spaced away from the main plane of extension.

### RELATED APPLICATION INFORMATION

The present application claims priority to and the benefit of German patent application no. 10 2013 216 901.9, which was filed in Germany on Aug. 26, 2013, the disclosure of which is incorporated herein by reference.

### FIELD OF THE INVENTION

The present invention proceeds from a micromechanical component.

### BACKGROUND INFORMATION

Micromechanical components of this kind, and methods for manufacturing them, are commonly known. For example, methods for manufacturing micromechanical sensors, such as acceleration sensors and rotation rate sensors, are commonly known.

With the known assemblages, microelectromechanical (MEMS) structures are, for example attached to the substrate of an MEMS element in such a way that, for example, encapsulating an MEMS element in a molding compound and/or soldering the MEMS element onto a circuit board can result in substrate warping, warping of individual MEMS structures, and/or undesired erroneous signals from the MEMS sensors. In addition, external vibrations can be coupled into the MEMS structures in such a way that undesired erroneous signals are produced. This is the case in particular when the resonant frequencies are in a frequency range of the external vibrations or spurious vibrations.

### SUMMARY OF THE INVENTION

An object of the present invention is therefore to furnish a micromechanical component and a method for manufacturing a micromechanical component, the micromechanical component being comparatively insensitive to warping and to vibrations coupled in from outside, and being more economical to manufacture.

The micromechanical component according to the present invention and the method according to the present invention for manufacturing a micromechanical component, in accordance with the coordinated claims, have the advantage as compared with the existing art that because the first sub-element is disposed on the second sub-element, the micromechanical component is comparatively insensitive to external mechanical stresses. In particular, the spring assemblage has a spring arrangement having a spring stiffness, the spring stiffness and/or a mass of the second sub-element being dimensioned such that the movable element is decoupled from external vibrations.

In particular, the spring arrangement are made at least partly or entirely of single-crystal silicone, very small initial deflections of the MEMS structures or of the movable element thereby being achieved.

The first sub-element of the movable element is made in particular, at least partly or entirely, from a single-crystal silicon material, the first sub-element being, in the first manufacturing step, for example etched out of and disengaged from a single-crystal silicon substrate. In particular, the second sub-element is made at least partly or entirely of a polysilicon material, the second sub-element being disposed, for example, along the normal direction (i.e. perpendicular to the main plane of extension) above the substrate, the second sub-element being, in particular in the second manufacturing step, formed from a polysilicon layer. In particular, the movable element is movably connected to the substrate, in particular exclusively, via the spring arrangement in the polysilicon layer, different potentials of the MEMS structure or of the first sub-element being guided outward in particular via the springs. In particular, the movable element is hermetically encapsulated with a cap wafer or with an encapsulation layer, the encapsulation layer in particular encompassing a polysilicon layer. In particular, the encapsulation layer is, which may be according to the present invention, a thin-layer encapsulation, the use of a thin-layer encapsulation advantageously enabling sensors having a comparatively low overall height to be manufactured and/or simultaneously, because of the comparatively good decoupling of the movable element from external stresses, also allowing manufacture of a micromechanical component or MEMS sensor having comparatively good performance.

According to the present invention, a connection of an element to the substrate here means, for example, an indirect connection of the element to the substrate, one or more intermediate elements—for example a connecting layer or oxide layer—being disposed between the element and the substrate. Alternatively, a connection of an element to the substrate here means, for example, a direct connection of the element to the substrate, i.e. for example without an intermediate element between the element and the substrate.

In particular, the micromechanical component is a micromechanical sensor, for example an acceleration sensor, a rotation rate sensor, or other sensor. In particular, the micromechanical component is provided for use in a motor vehicle.

Advantageous embodiments and refinements of the invention may be gathered from the dependent claims and from the description, with reference to the drawings.

According to a refinement, provision is made that the movable element encompasses a third sub-element connected to the second sub-element, the third sub-element extending mainly along a further functional plane, the further functional plane being disposed substantially parallel to the main plane of extension of the substrate, the further functional plane being spaced away from the functional plane and from the main plane of extension, the functional plane being disposed, along a normal direction substantially perpendicular to the main plane of extension, between the main plane of extension of the substrate and the further functional plane.

It is thereby advantageously possible for the movable element to have a third sub-element that may be made of a polysilicon material, the third sub-element in particular being formed at least partly or entirely from a further polysilicon layer. For example, the third sub-element is disposed, in particular overlappingly, along the normal direction or along a projection direction parallel to the normal direction, between the substrate and the second sub-element. In particular, an in particular electrically insulating connecting layer or oxide layer is disposed, at least in sub-regions, between the second and the third sub-element. In particular, the first sub-element etched out of the substrate, or the MEMS structure, is/are coupled to the third sub-element, i.e. for example are connected to one another, via the connecting layer. In particular, the movable element is movably connected to the substrate, in particular exclusively, via at least two spring arrangement in the polysilicon layer and/or in the further polysilicon layer, different potentials of the MEMS structure or of the first sub-element being guided outward in particular via the springs.

According to a refinement, provision is made that the first sub-element has a single-crystal silicon material, the second sub-element and/or the third sub-element having a polysilicon material. According to a refinement, provision is made that the first sub-element is connected via a connecting layer, in particular an oxide layer, to the second sub-element.

It is thereby advantageously possible for the second sub-element to be formed from a functional layer connected to the substrate and/or for the third sub-element to be formed from a further functional layer connected to the functional layer and for the first sub-element to be formed from the substrate material. This advantageously furnishes a movable element extending along a projection direction parallel to the normal direction through the functional plane and main plane of extension and/or further functional plane, which element is attached by way of the spring arrangement assemblage to the substrate, the spring arrangement assemblage being formed exclusively from the functional layer and/or from the further functional layer or having spring arrangement formed exclusively therefrom.

According to a refinement, provision is made that the second sub-element has a layer thickness extending along a projection direction parallel to the normal direction, the third sub-element having a further layer thickness extending along the projection direction, the further layer thickness being greater than the layer thickness.

It is thereby advantageously possible for the layer thickness to be between 0.4 and 400 micrometers, which may be between 0.7 and 250 micrometers, very particularly may be between 0.8 and 200 micrometers. Furthermore, the further layer thickness is between 10 nanometers and 75 micrometers, which may be between 25 nanometers and 30 micrometers, very particularly may be between 50 nanometers and 15 micrometers.

According to a refinement, provision is made that the movable element is connected to the substrate by way of the spring arrangement assemblage, in particular exclusively, via the second sub-element and/or third sub-element.

It is thereby advantageously possible for the MEMS structure or the first sub-element to be disposed internally, i.e. within a cavity of the micromechanical component, on the disengaged second sub-element, i.e. for example on a second sub-element embodied as a comparatively thick polysilicon plate, the second sub-element being connected to the substrate via comparatively soft springs. External mechanical stresses are thereby advantageously not transferred via the comparatively soft springs to the MEMS structure or to the first sub-element, or to the movable element as a whole. The micromechanical component is thus comparatively insensitive to mechanical stresses and/or external vibrations, which as a result may be not coupled in.

According to a refinement, provision is made that the spring arrangement assemblage encompasses at least two spring arrangement attaching the movable element to the substrate, the at least two spring arrangement extending mainly along the functional plane and/or further functional plane.

It is thereby advantageously possible for the spring stiffness of the at least two spring arrangement, and/or a mass of the second sub-element, to be dimensioned in such a way that the movable element is decoupled from external vibrations.

According to a refinement, provision is made that the micromechanical component has a connecting means, the first sub-element, the second sub-element, and/or the third sub-element being electrically conductively connected to the connecting arrangement via the spring arrangement assemblage.

It is thereby advantageously possible for electrical signals detected by the movable element to be guided outward via the spring arrangement assemblage.

According to a refinement of the method according to the present invention, provision is made that in the second manufacturing step a third sub-element extending mainly along a further functional plane is connected to the second sub-element, the further functional plane being disposed substantially parallel to the main plane of extension of the substrate, the further functional plane being disposed spaced away from the main plane of extension of the substrate and from the functional plane, the functional plane being disposed, along a normal direction substantially perpendicular to the main plane of extension, between the main plane of extension of the substrate and the further functional plane, in the third manufacturing step the movable element being formed from the first, second, and third sub-element.

It is thereby advantageously possible to furnish a comparatively inexpensive and small micromechanical component. A micromechanical component having a comparatively low sensitivity to mechanical stresses and/or to external vibrations is thereby furnished. In particular, in the second manufacturing step the third sub-element is formed from a further polysilicon layer.

According to a refinement of the method according to the present invention, provision is made that the movable element is connected to the substrate by way of the spring arrangement assemblage, in particular only, via the second sub-element and/or third sub-element.

It is thereby advantageously possible for the micromechanical component to be less sensitive to external stresses and/or spurious vibrations, and capable of being manufactured more economically.

According to a refinement of the method according to the present invention, provision is made that in a fourth manufacturing step the micromechanical component is hermetically encapsulated using an encapsulating arrangement, the encapsulating arrangement being formed from a wafer material or a polysilicon material.

It is thereby advantageously possible to furnish, when an encapsulating arrangement made of a polysilicon material is used, a micromechanical component encapsulated by thin-layer encapsulation, the micromechanical component on the one hand having a comparatively low overall height while on the other hand, because of comparatively good decoupling of external stresses, the performance of the sensor can be improved.

Exemplifying embodiments of the present invention are depicted in the drawings and are explained in further detail in the description that follows.

### BRIEF DESCRIPTION OF THE DRAWINGS

FIGS. 1 and 2 show various embodiments of the micromechanical component of the present invention.

FIGS. 3 to 16 show a method for manufacturing a micromechanical component in accordance with an embodiment of the present invention.

FIGS. 17 to 28 show a method for manufacturing a micromechanical component in accordance with an embodiment of the present invention.

FIGS. 29 to 31 show various embodiments of the micromechanical component of the present invention.

### DETAILED DESCRIPTION

In the various Figures, identical parts are always labeled with the same reference characters and are therefore as a rule also each recited or mentioned only once.

In the various Figures, a first direction 101 substantially parallel to main plane of extension 100 of the substrate is referred to as X direction 101, a second direction 102 substantially parallel to main plane of extension 100 and substantially perpendicular to X direction 101 is referred to as Y direction 102, and a third direction 103 substantially perpendicular to main plane of extension 100 is referred to as Z direction 103 or normal direction 103.

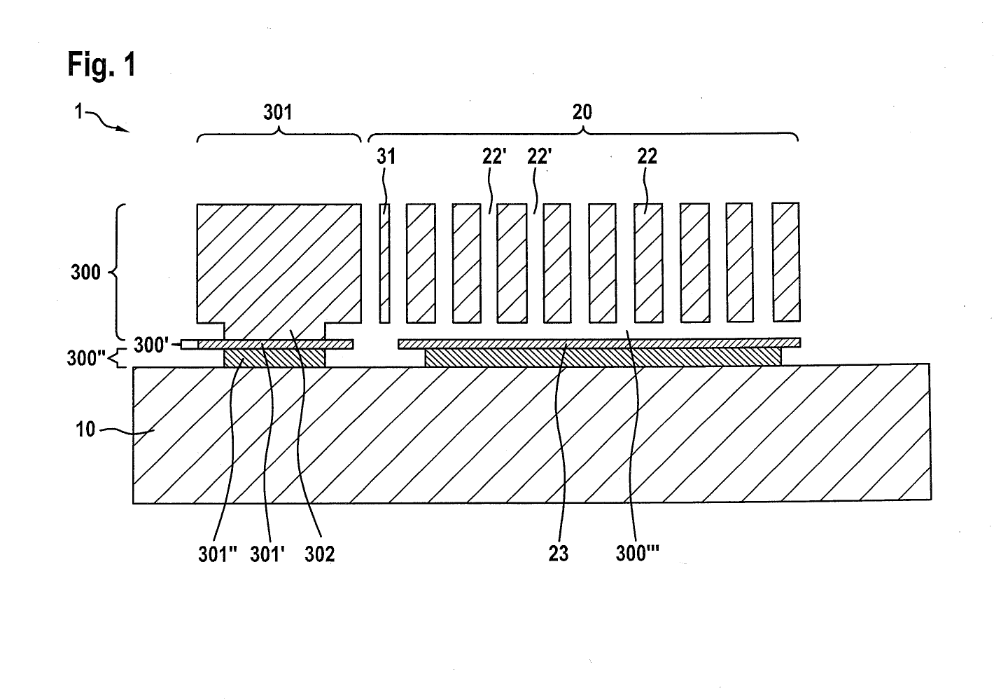

FIG. 1 depicts an embodiment of micromechanical component 1 of the present invention. A micromechanical component of this kind is, for example, an acceleration sensor and/or a rotation rate sensor. The micromechanical component has a movable element 20, movable element 20 being deflectable out of a rest position, i.e. a rest location, into a deflected position or deflection position (not depicted). Movable element 20 has for this purpose a spring arrangement assemblage with which movable element 20 is attached or anchored to a substrate 10 of micromechanical component 1. A deflection motion, for example because of an external acceleration or rotation rate, of movable element 20 is detected in particular capacitively, i.e. as a function of a change in capacitance between movable element 20 and an electrode 23′. Movable element 20 here encompasses a movable silicon structure 22. In a method for manufacturing a micromechanical component of this kind, in a first step movable silicon structure 22 is generated by way of an etching method from a comparatively thick functional layer 300, i.e. one having a layer thickness of several micrometers, in particular from a so-called epi-poly layer 300. Trenches 22′ having a comparatively high aspect ratio are generated in this context in functional layer 300, in particular in movable silicon structure 22. In a second step a sacrificial layer 300′″, in particular an oxide layer 300′″, beneath the comparatively thick silicon structure 22 is removed. In particular, structures having a comparatively narrow, elongated extent are also generated in functional layer 300, which structures are formed in particular as spring arrangement 31 or springs 31 of a spring arrangement assemblage 30. It is thereby advantageously possible to manufacture structures 20, or a movable element 20, that are movable relative to substrate 10 and attached resiliently to the substrate. In particular, a further functional layer 300′, in particular a further polysilicon layer, is disposed beneath functional layer 300 or beneath silicon structure 22 of movable element 20. A suspension mount 301′ or partial suspension arrangement 301′ for movable element 20 or for fixed silicon structures, and/or an electrode 23′ beneath movable element 20, and/or a conductor path can be formed, for example, from further functional layer 300′.

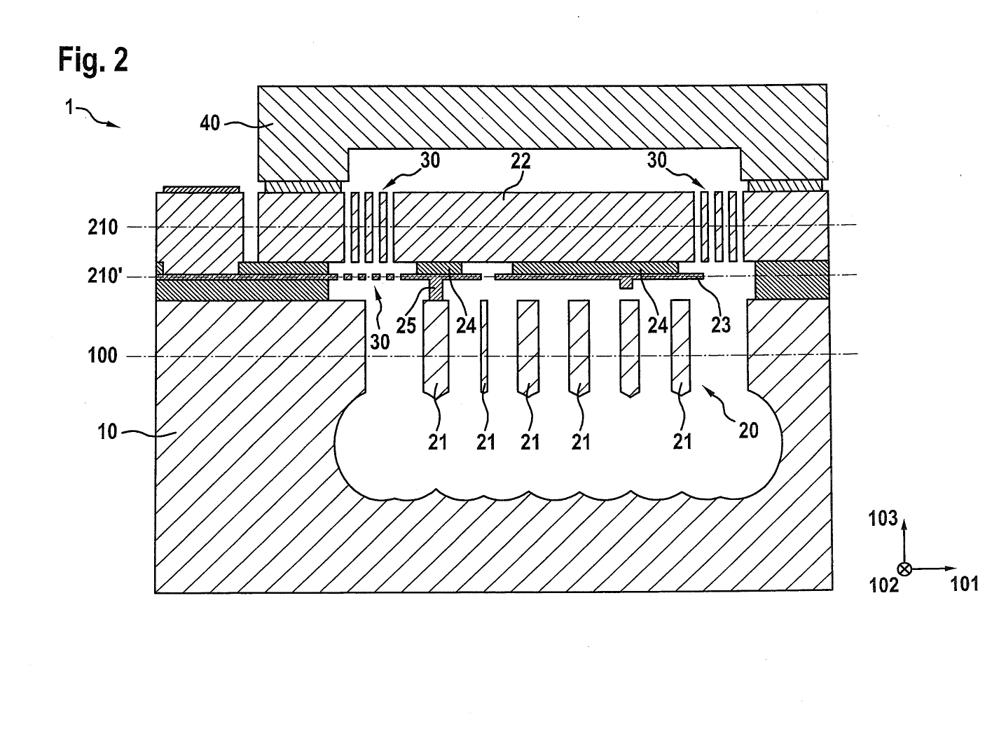

Here the movable and/or fixed structures 20, 301 in functional layer 300 that are to be disengaged are equipped with a plurality of recesses 22′ or trenches 22′ in such a way that they become patterned out, i.e. under-etched and thus disengaged, in a sacrificial etching methods. This causes formation, for example, of a suspension arrangement 301, a contact arrangement 302 firstly being generated between functional layer 300 and the comparatively thin further functional layer 300′ located therebeneath. Further functional layer 300′ is here indirectly connected or coupled to the substrate via a connecting layer 300″ (here an oxide layer 300″) disposed between further functional layer 300′ and substrate 10. The further functional layer has a lateral extent, parallel to a main plane of extension 100 (see FIG. 2) of substrate 10, that is sufficiently large, for example, that oxide layer 300″ that is disposed between further functional layer 300′ and the substrate is not completely removed.

FIG. 2 depicts an embodiment of micromechanical component 1 of the present invention. Here micromechanical component 1 has a substrate 10 having a main plane of extension 100, a movable element 20, and a spring arrangement assemblage 30 attached to substrate 10. Movable element 20 is attached to substrate 10 by way of spring arrangement assemblage 30. Movable element 20 here is, in particular, attached to the substrate not directly but instead indirectly via multiple layers. Movable element 20 is deflectable out of a rest position into a deflection position. Movable element 20 furthermore encompasses a first sub-element 21 and a second sub-element 22 connected to first sub-element 21, as well as here a third sub-element 23 connected to second sub-element 22 and to first sub-element 21. This means here, for example, that third sub-element 23 is disposed along normal direction 103 between first sub-element 21 and second sub-element 22. Here first sub-element 21 extends mainly along main plane of extension 100 of substrate 10, which means that first sub-element 21 is formed from the substrate material. In addition, second sub-element 22 extends mainly along a functional plane 200 and/or third sub-element 23 extends mainly along a further functional plane 200′, functional plane 200 and/or further functional plane 200′ being disposed substantially parallel to main plane of extension 100 of substrate 10, and functional plane 200 and/or further functional plane 200′ being spaced away from main plane of extension 100 of the substrate and/or from one another.

In addition, second sub-element 22 is here connected via a connecting layer 24 to third sub-element 23. In particular, connecting layer 24 is an oxide layer, the second sub-element being, for example, electrically insulated from the third sub-element. Furthermore, first sub-element 21 here is connected directly, in particular electrically conductively, to third sub-element 23 via a connecting element 25.

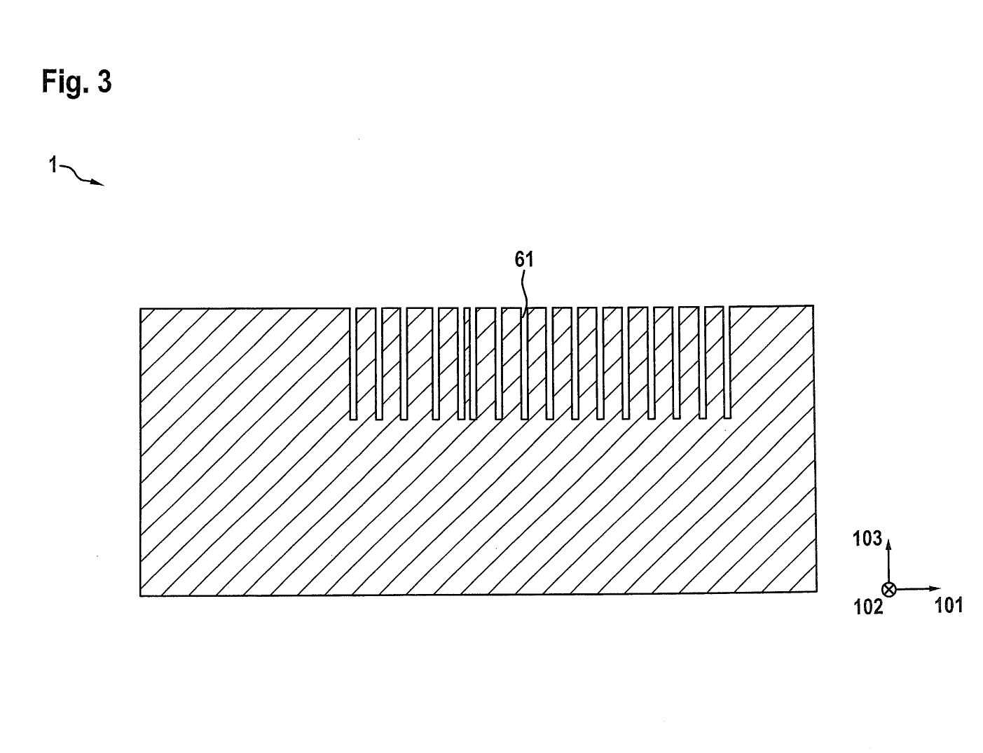

FIGS. 3 to 16 depict a method for manufacturing a micromechanical component 1 in accordance with an embodiment of the present invention. What is described in particular with reference to FIGS. 3 to 15 is a method for manufacturing a micromechanical component 1 having an encapsulating arrangement 40 formed from a wafer material.

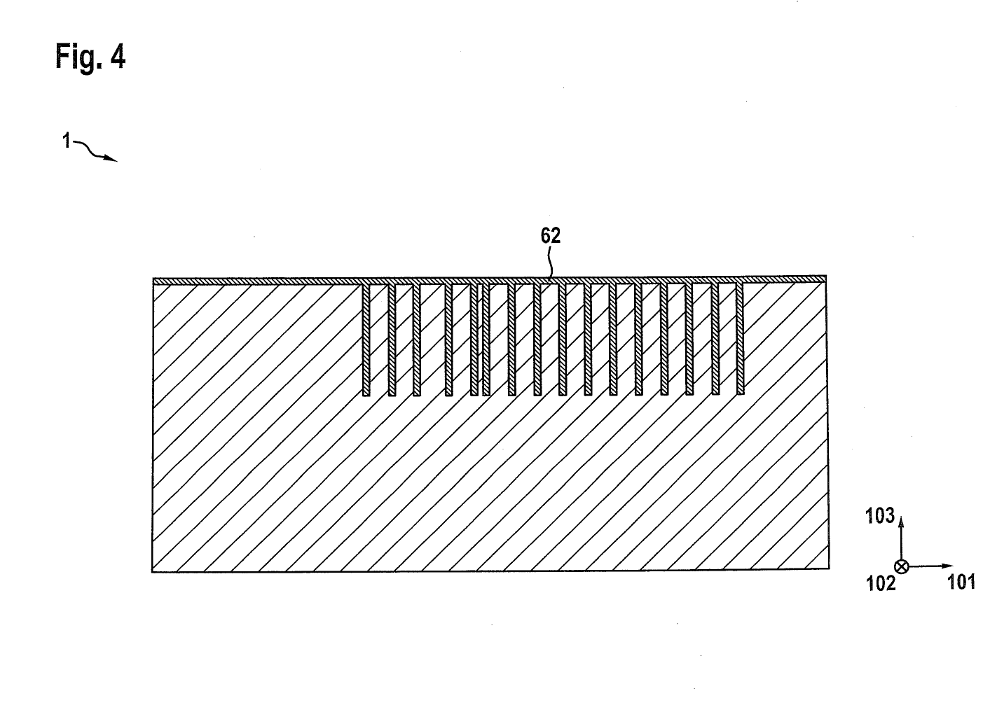

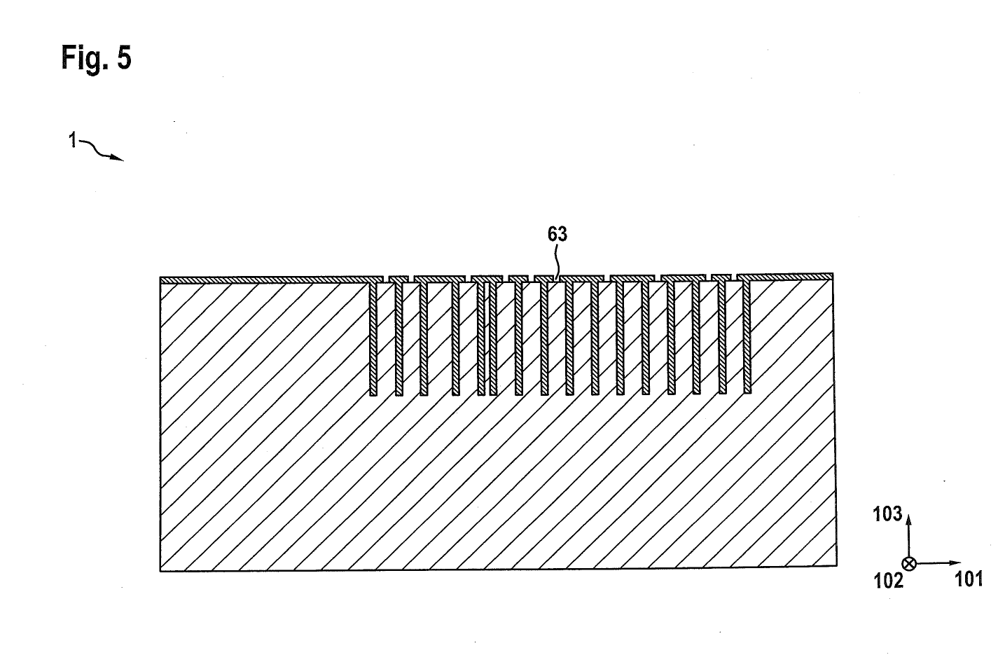

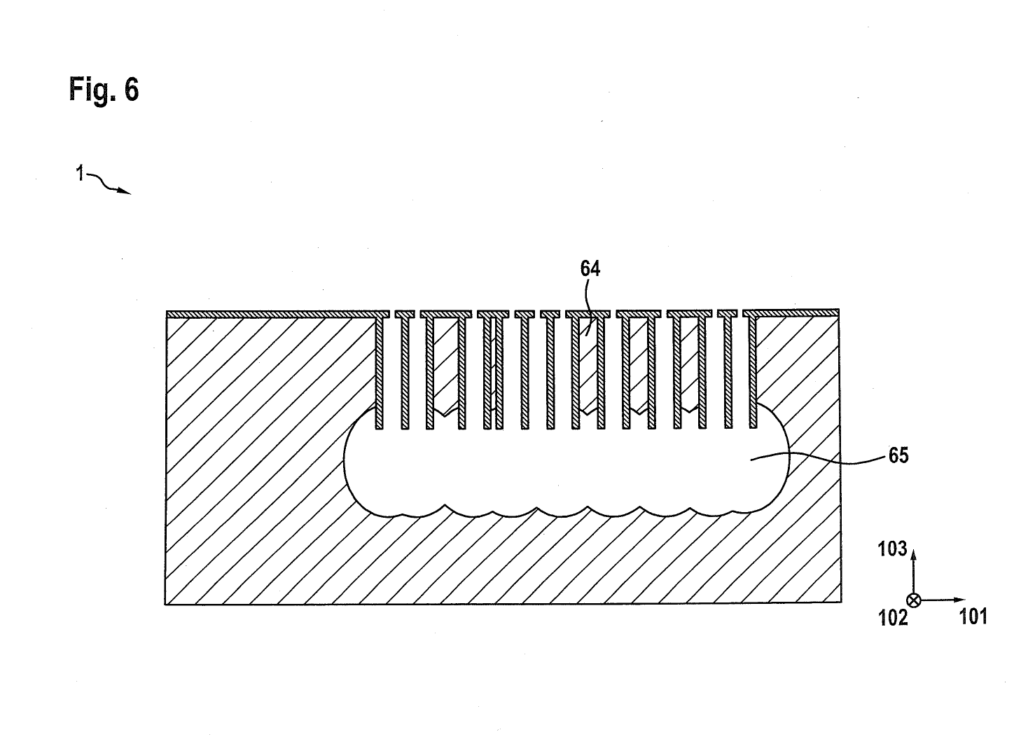

In a first manufacturing step a substrate 10 exhibiting a main plane of extension is furnished, a first sub-element 21 extending mainly along main plane of extension 100 of substrate 10 being formed out of the substrate material. As shown in FIG. 3, in a first sub-step a trench structure 61 is etched into the substrate, trench structure 61 having a plurality of trenches, each trench of trench structure 61 extending mainly, in particular substantially linearly, parallel to normal direction 103 along a trench length, and extending parallel to main plane of extension 100 along a trench width, the trench length may exceed the trench width by at least an order of magnitude. All the trench lengths may be disposed parallel to one another. In a second step, trench structure 61 is then closed off by a first sub-layer 62, in particular encompassing an oxide material (FIG. 4). In a third sub-step, openings 63 extending mainly parallel to normal direction 103 and completely through the first sub-layer are etched into first sub-layer 62 (FIG. 5). In a fourth sub-step depicted in FIG. 6, the silicon material of substrate 10 disposed between the oxide-filled trenches of trench structure 61 are etched out by isotropic silicon etching through openings 63. In this context, in particular elongated finger elements 64, i.e. ones extending mainly parallel to normal direction 103, are completely under-etched in the silicon material of substrate 10. This generates disengaged silicon structures 64 that here are in particular connected to substrate 10 only via the oxide filling. In particular, this generates a continuous cavity 65 that, for example, almost completely surrounds the disengaged silicon structures 64.

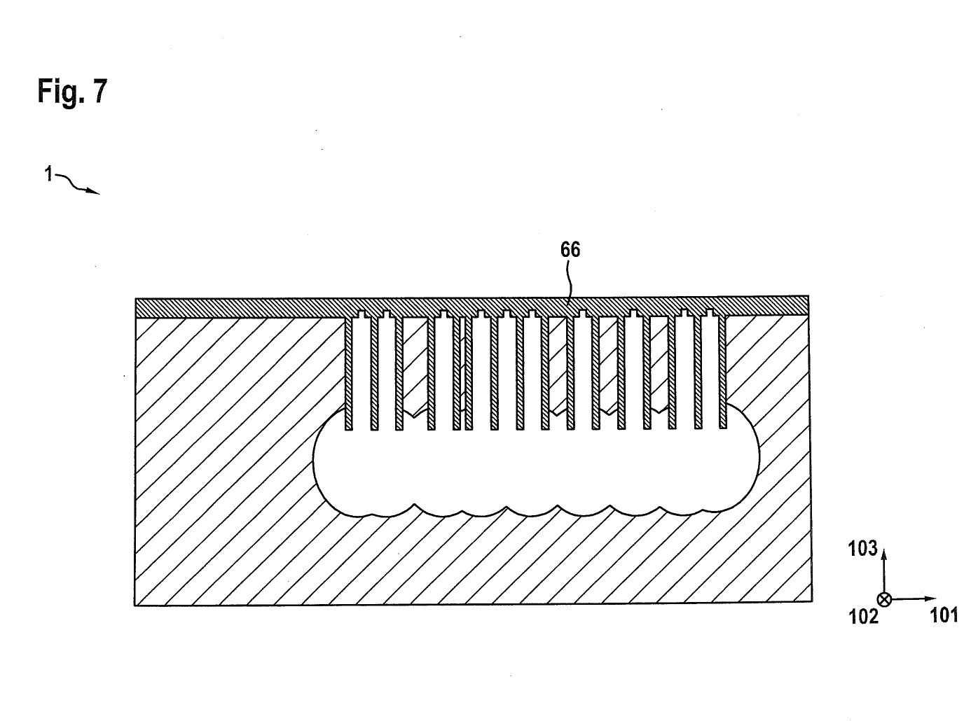

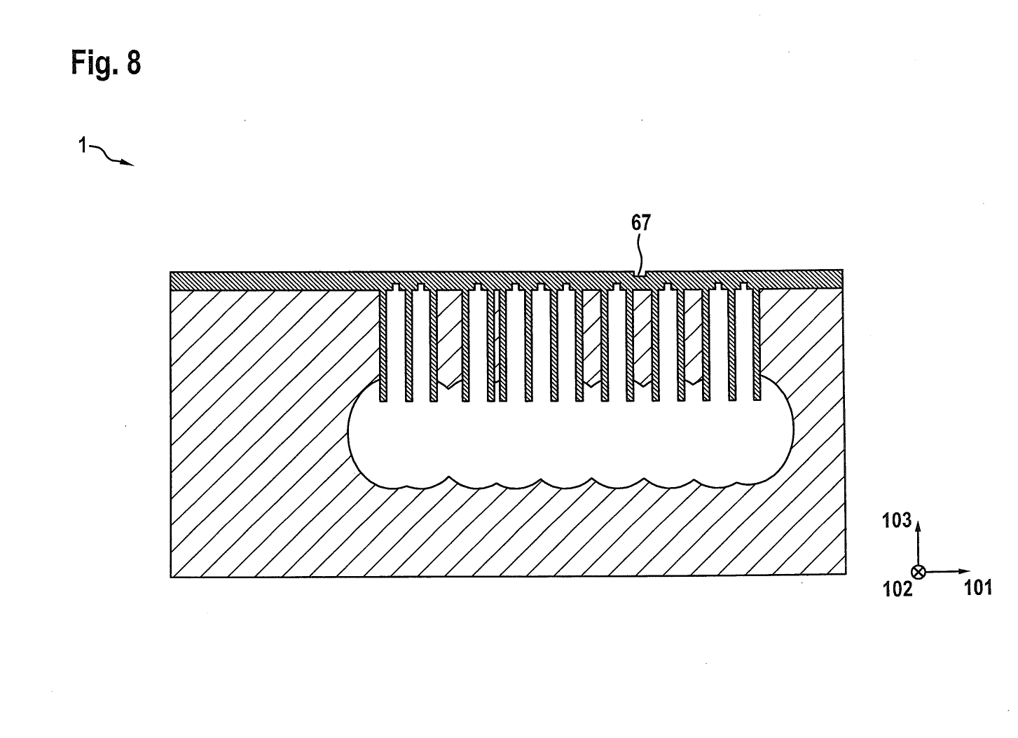

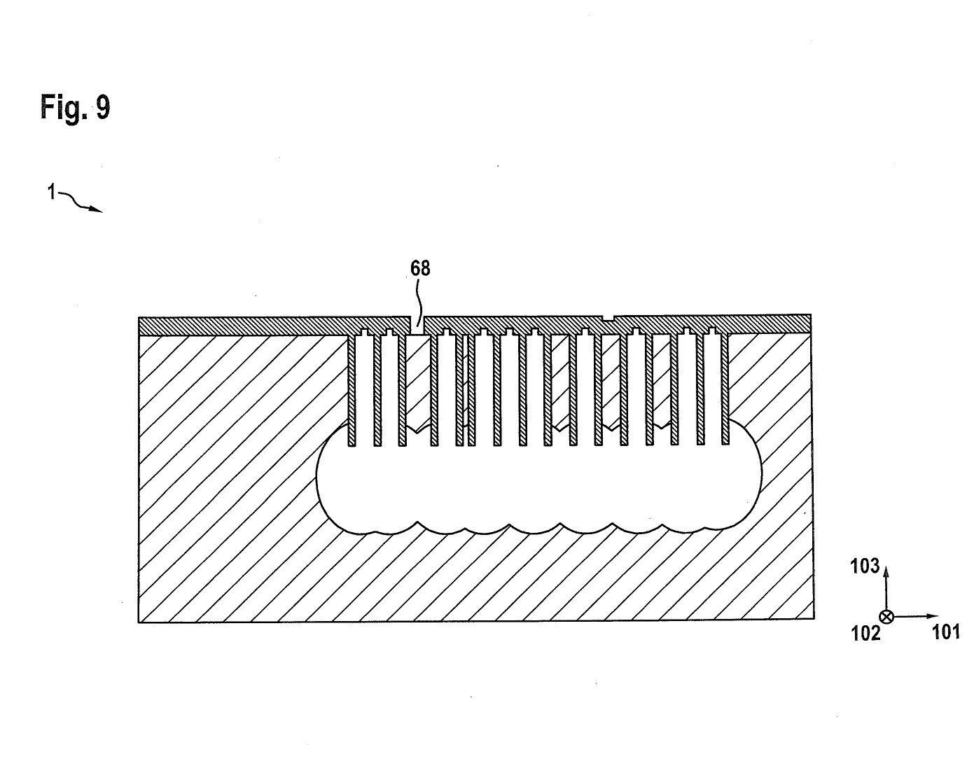

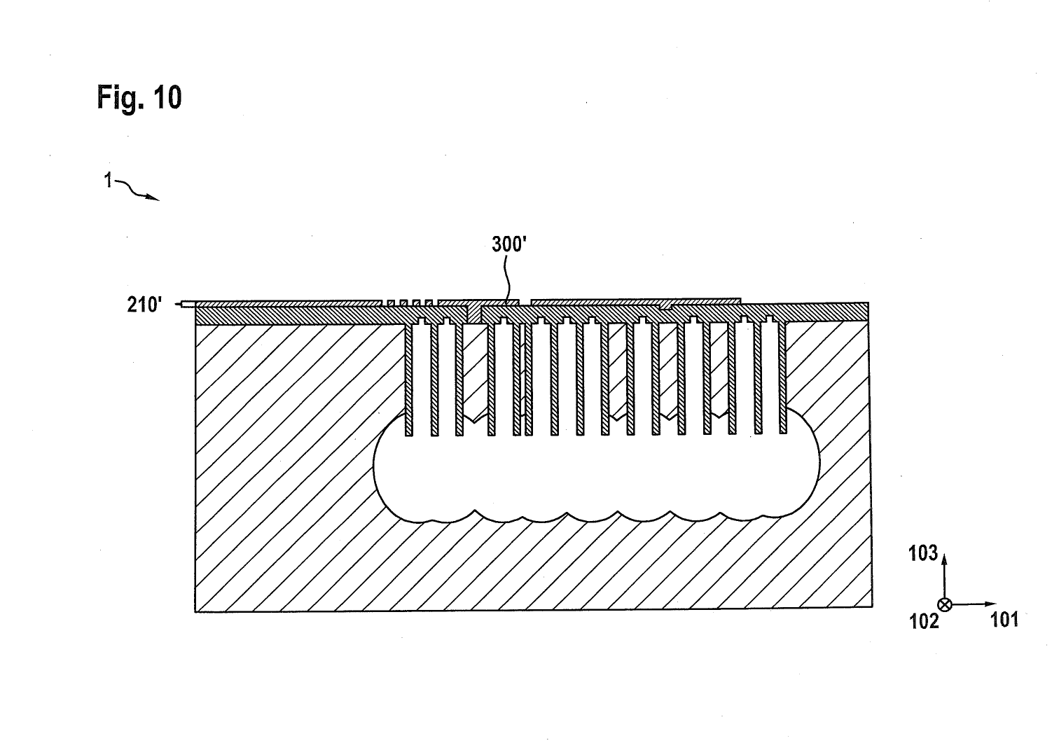

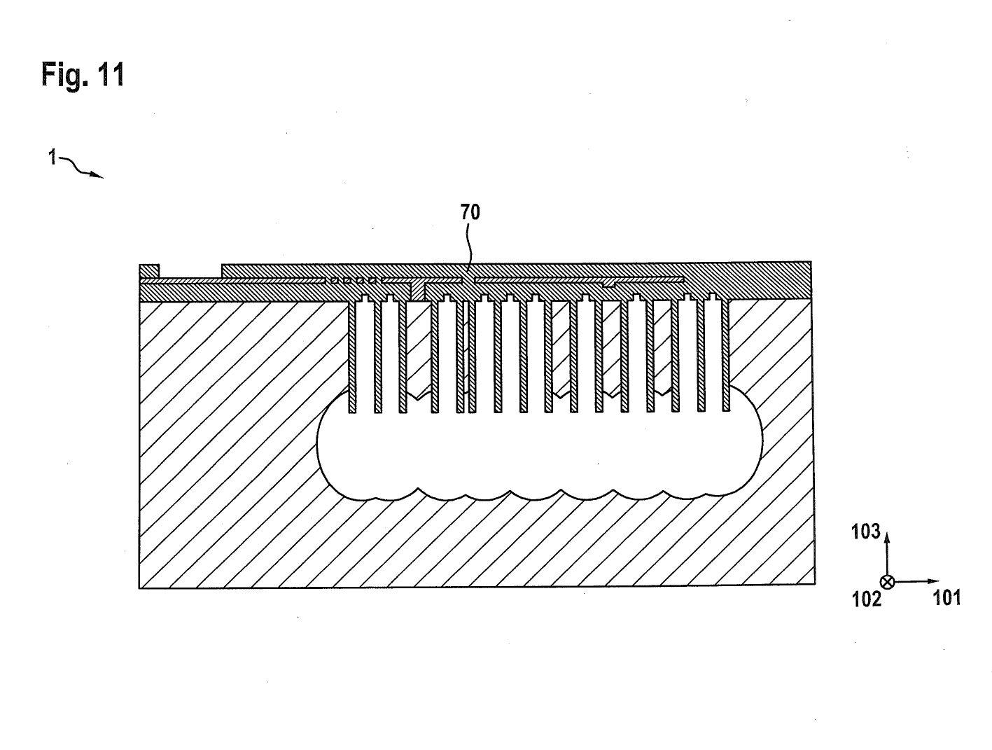

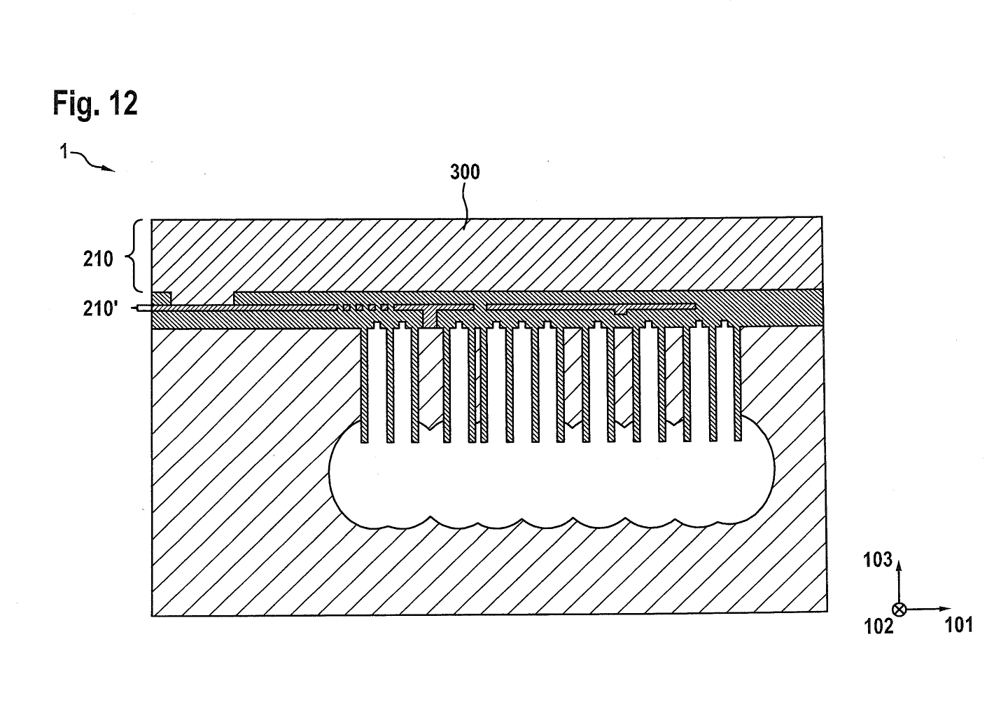

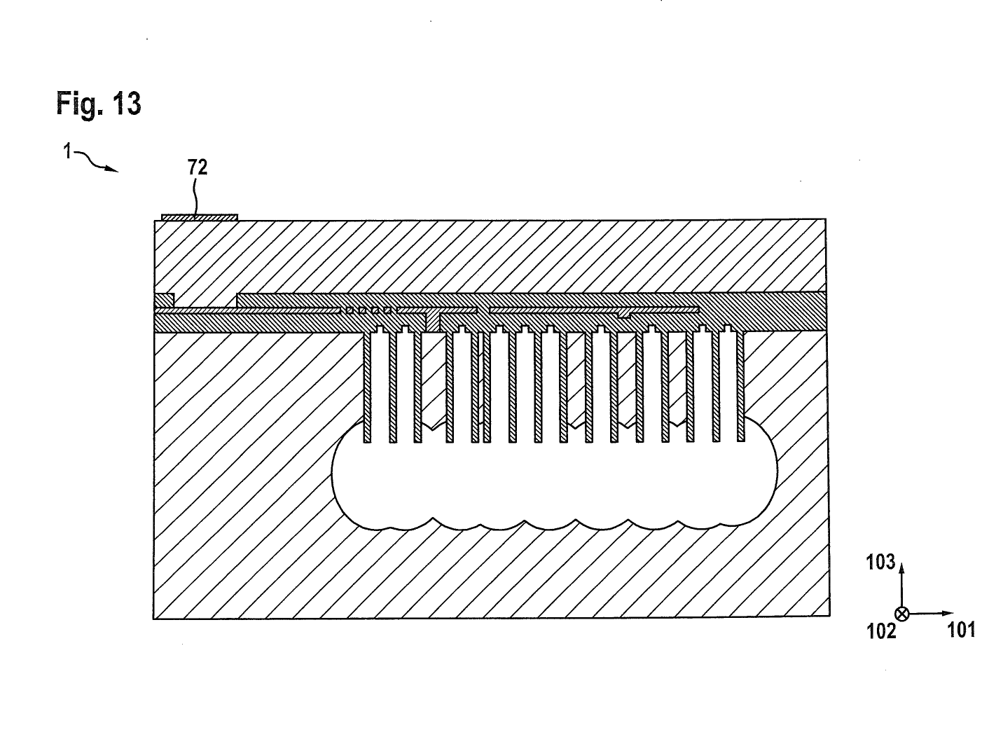

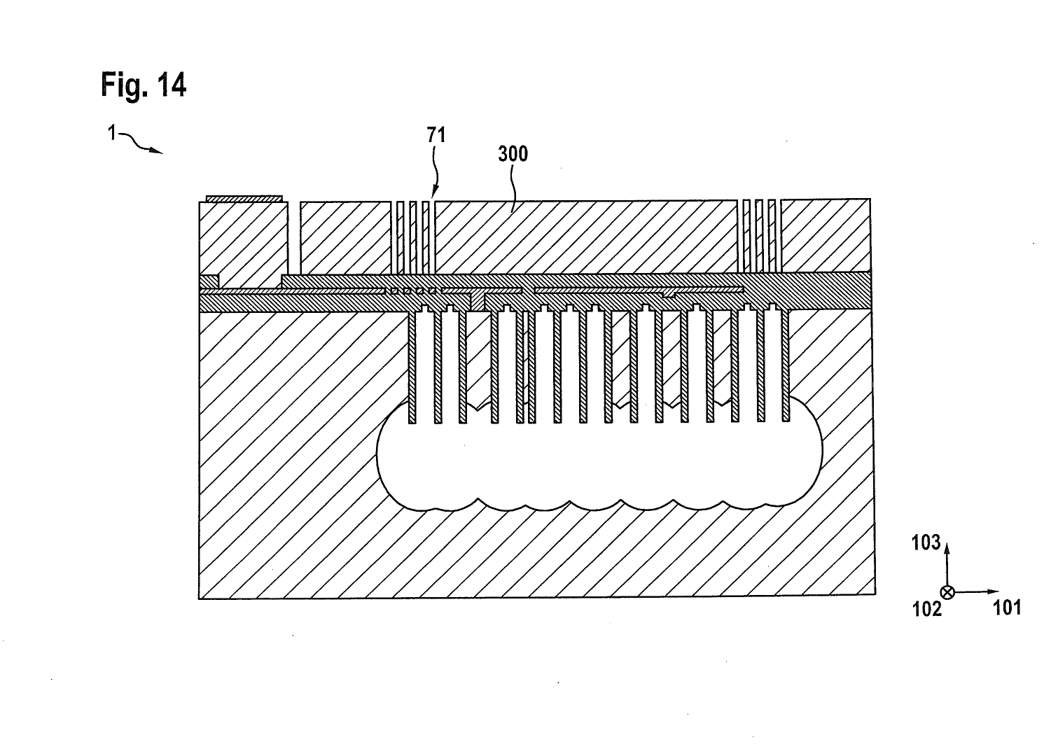

In a second manufacturing step a second sub-element 22 extending mainly along a functional plane 200 is connected to first sub-element 21, functional plane 200 being disposed substantially parallel to main plane of extension 100 of substrate 10, functional plane 200 being disposed spaced away from main plane of extension 100. For this, in a fifth sub-step depicted in FIG. 7, firstly openings 63 in first sub-layer 62 are closed of by way of a second sub-layer, in particular a further oxide deposit. In a sixth sub-step depicted in FIG. 8, depressions 67 are optionally etched into second sub-layer 66, the depressions being configured in such a way that in the subsequent manufacturing steps or sub-steps, an elevation extending parallel to normal direction 103 is generated in the further functional layer and is provided, for example, as a stop for movable element 20. In a seventh sub-step depicted in FIG. 9, a contact region 68 is etched into second sub-layer 66. In an eighth sub-step depicted in FIG. 10, further functional layer 300′ (in particular a first polysilicon layer) extending mainly along further functional plane 200′ is deposited and patterned; this extends parallel to normal direction 103 along a further layer thickness 210′. The further layer thickness may be between 50 nanometers and 15 micrometers. Areas that have a minimum diameter may be formed from first polysilicon layer 69, the minimum diameter being greater than twice the depth of a cavity generated by under-etching in subsequent sacrificial oxide etching steps, the depth extending in particular parallel to normal direction 103. In a ninth sub-step depicted in FIG. 11, a third sub-layer made in particular of an oxide material is deposited and patterned. In a tenth sub-step depicted in FIG. 12, a functional layer 300 (which may be a second polysilicon layer 300, particularly may be an epi-poly layer), extending mainly along functional plane 200, is deposited. Functional layer 300 may have a layer thickness 210, extending parallel to normal direction 103, that is greater than further layer thickness 210′. Layer thickness 210 may be between 0.8 and 200 micrometers. Optionally, in an eleventh sub-step depicted in FIG. 13, a metal layer 72, in particular an aluminum layer 72, is deposited and patterned. In a twelfth sub-step depicted in FIG. 14, functional layer 300 is patterned or a structure 71 having a plurality of trenches is formed.

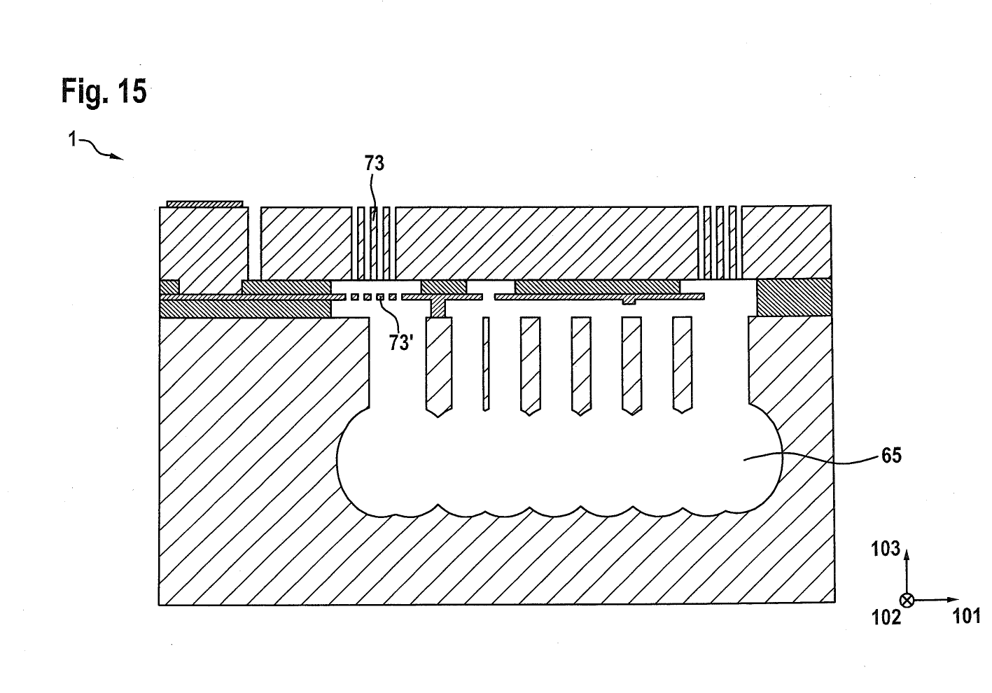

In a third manufacturing step a movable element 20 is constituted from first sub-element 21 and second sub-element 22, movable element 20 being attached by way of a spring arrangement assemblage 30 to substrate 10, movable element 20 being disposed in such a way that the movable element is deflectable out of a rest position into a deflection position. In a thirteenth sub-step depicted in FIG. 15, the MEMS structures are etched out of substrate 10, i.e. movable element 20 is disengaged, using a sacrificial layer etching method, in particular using a gas-phase etching method utilizing hydrofluoric acid (HF). Etching openings 73, 73′ that correspond to one another, i.e. that at least partly or entirely overlap along a projection direction parallel to normal direction 103, which are located in particular above the oxide layers of the MEMS structure in the substrate, may be generated in first and/or second functional plane 200, 200′. It is thereby advantageously possible to carry out etching at first comparatively quickly along normal direction 103 in the direction of the substrate, and then to distribute the etching medium in a cavity 65 of substrate 10 beneath the MEMS structures parallel to main plane of extension 100 and to remove oxide 62, 66, 70 from there.

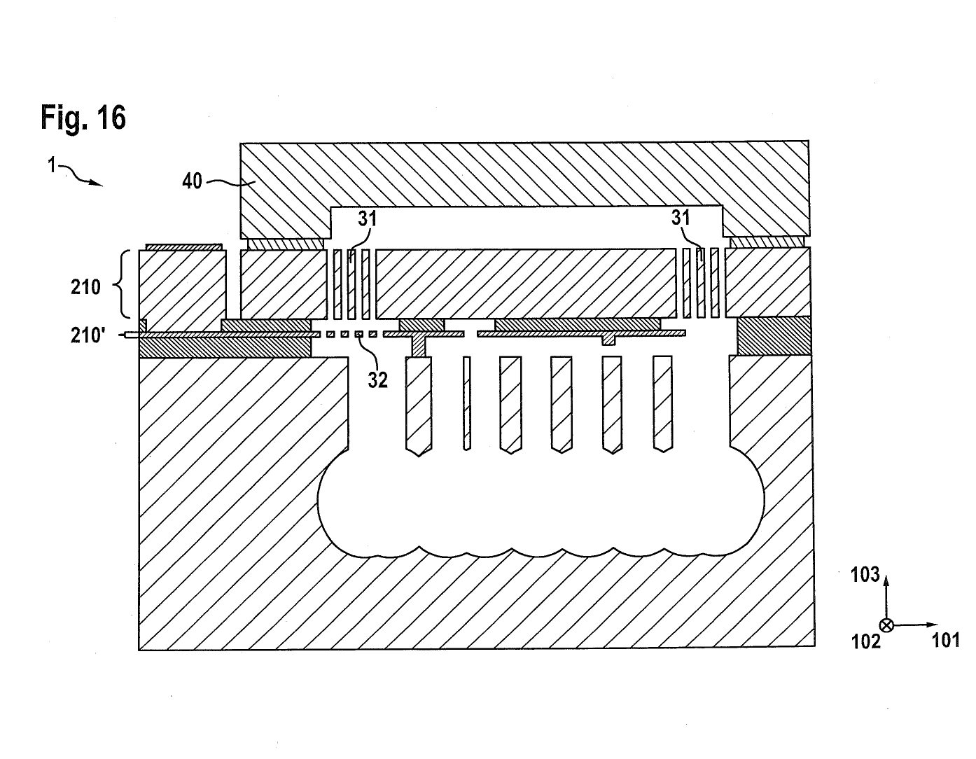

In a fourth manufacturing step, micromechanical component 1 is hermetically encapsulated by way of an encapsulating arrangement 40, encapsulating arrangement 40 being formed from a wafer material; in a fourteenth sub-step depicted in FIG. 16, micromechanical component 1 is hermetically sealed with a cap wafer 40 using a bonding method.

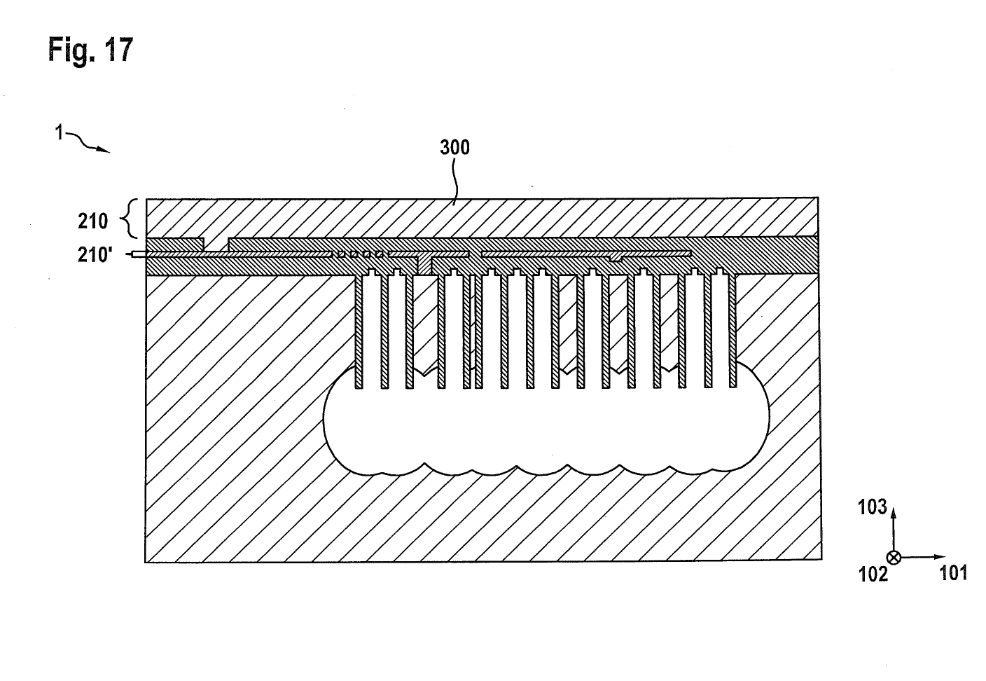

FIGS. 17 to 28 depict a method for manufacturing a micromechanical component 1 in accordance with an embodiment of the present invention. What is described here is in particular a manufacturing method for manufacturing a micromechanical component having a thin-layer cap.

In the first manufacturing step a substrate 10 having a main plane of extension is furnished, a first sub-element 21 extending mainly along main plane of extension 100 of substrate 10 being formed from the substrate material, the first to fourth sub-steps (FIGS. 3 to 6) being performed.

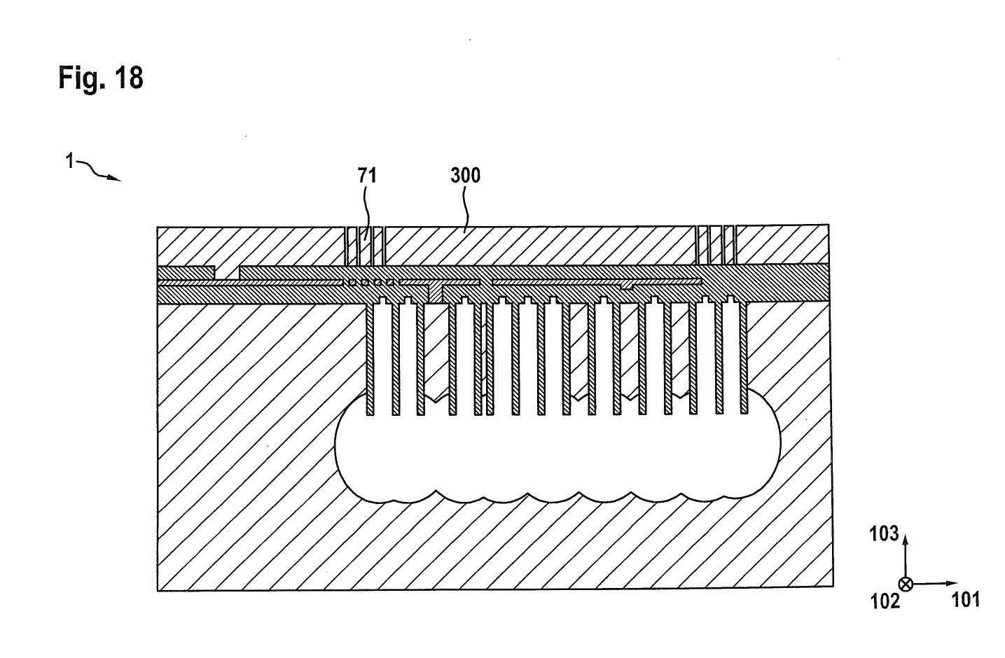

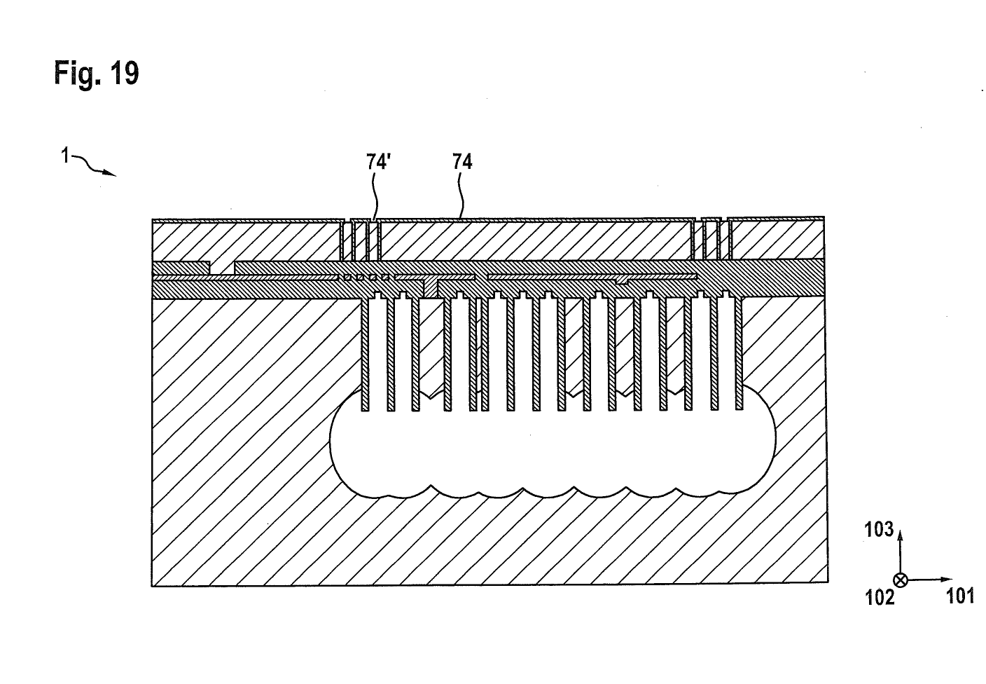

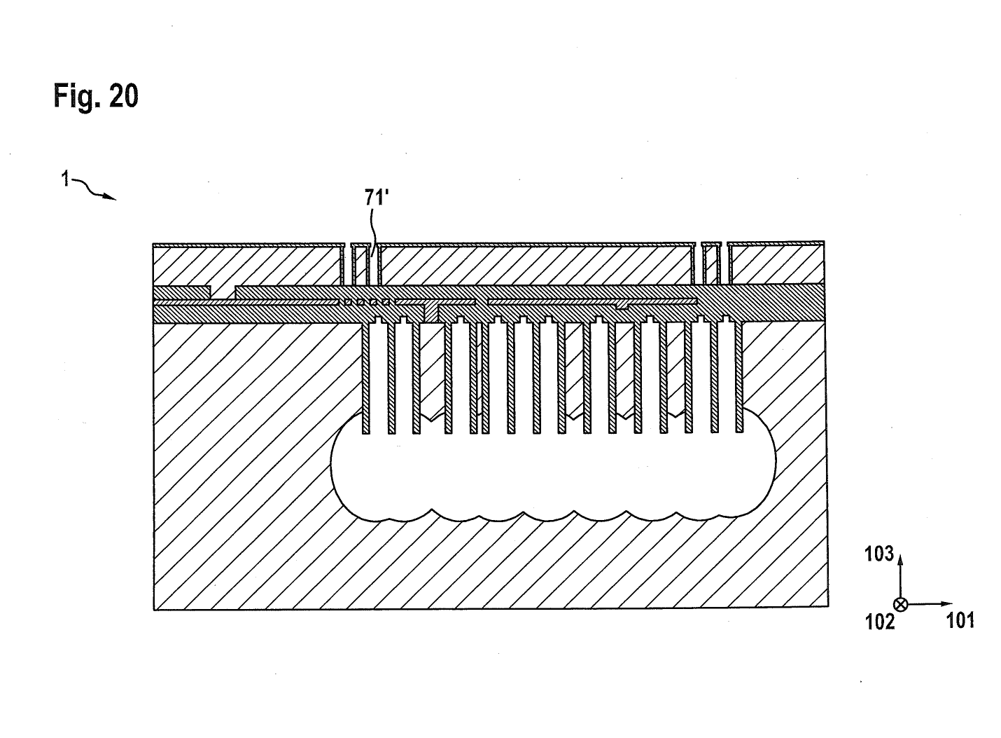

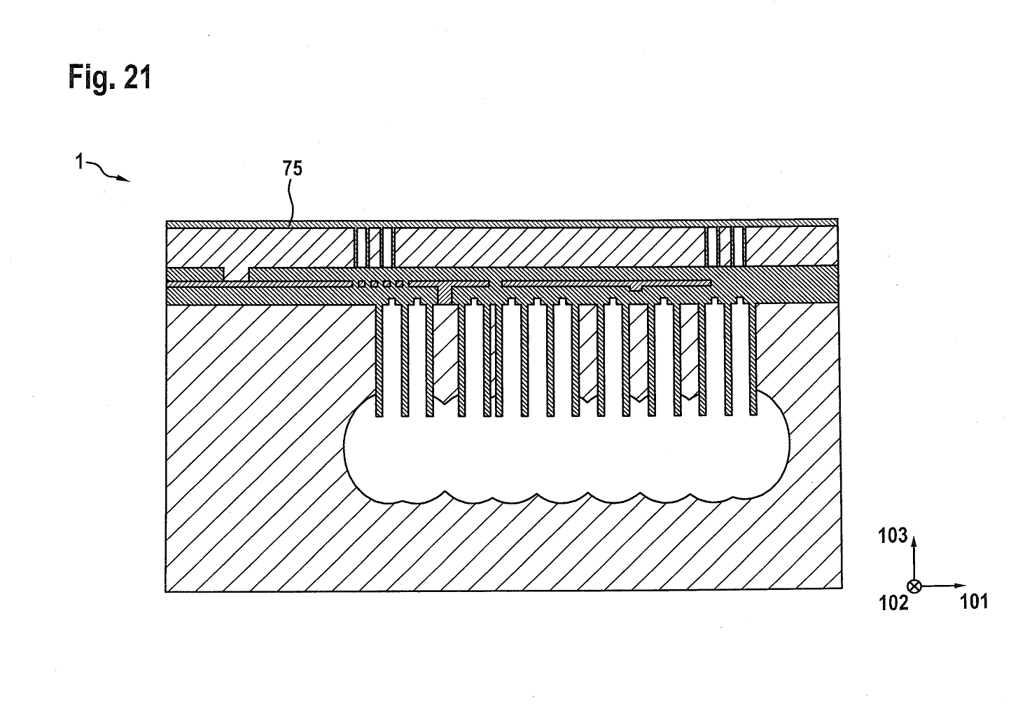

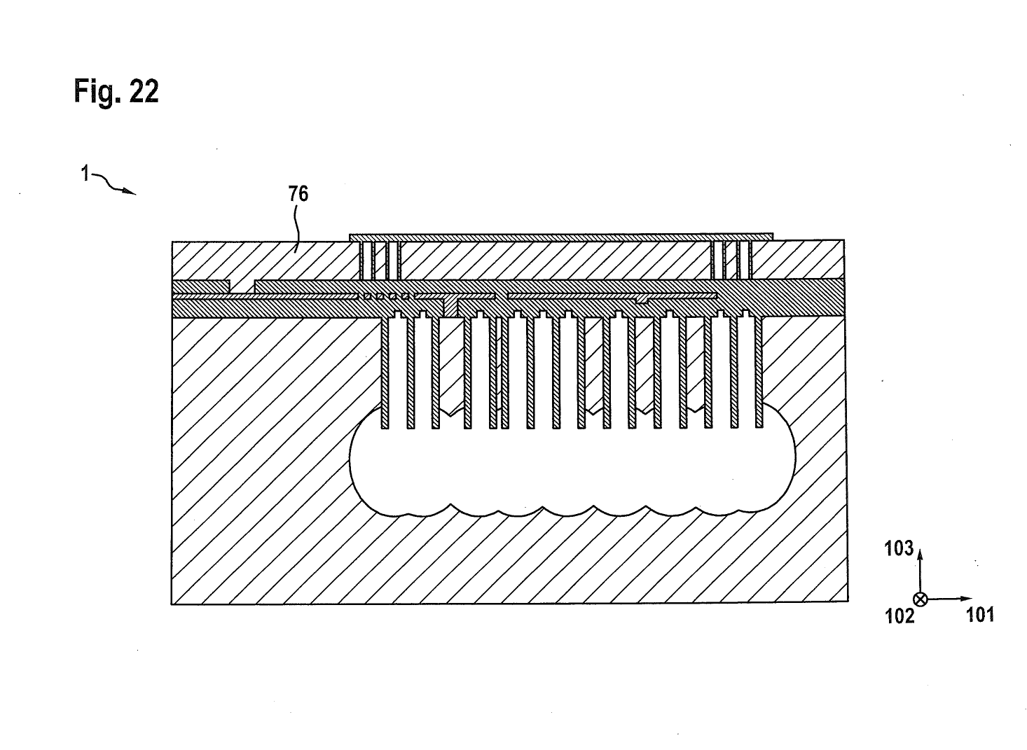

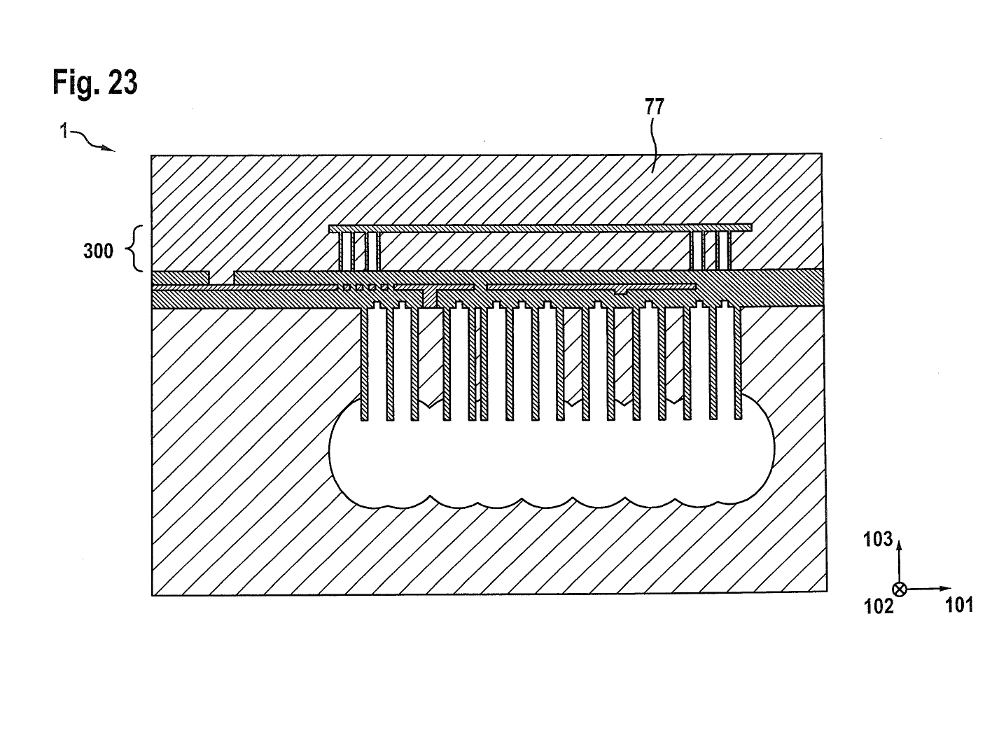

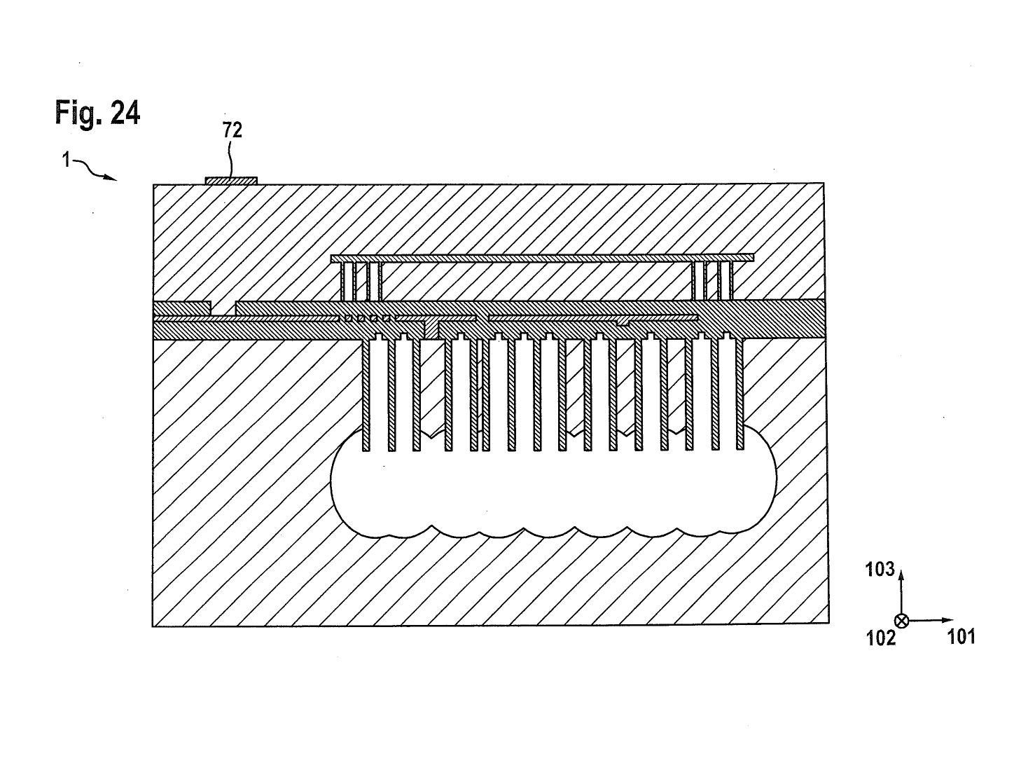

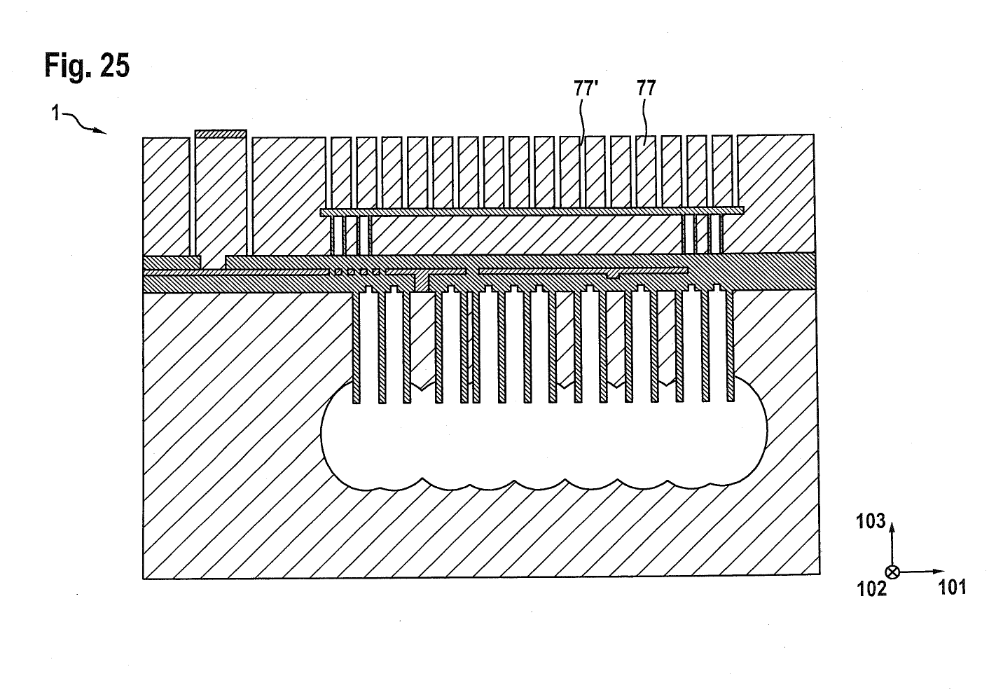

In the second manufacturing step a second sub-element 22 extending mainly along a functional plane 200 is connected to first sub-element 21, functional plane 200 being disposed substantially parallel to main plane of extension 100 of substrate 10, functional plane 200 being disposed spaced away from main plane of extension 100, the fifth to tenth sub-steps (FIGS. 7 to 12) being performed, micromechanical component 1 being manufactured in a fifteenth sub-step depicted in FIG. 17. In particular, sub-steps eleven to fourteen are not performed here. In a sixteenth to nineteenth sub-step depicted in FIGS. 18 to 21, functional layer 300, which may be a second polysilicon layer 300, is deposited and patterned. Here in particular, in accordance with a first alternative, a trench structure 71 having a plurality of trenches is etched into functional layer 300, the trenches extending parallel to the main plane of extension along a trench width, subsequently a fifth sub-layer 75, in particular a respective oxide layer, being deposited, the trench width may be less than 100%, which may be less than 75%, very particularly may be less than 50% of the extent of fifth sub-layer 75 along a projection direction parallel to normal direction 103. In accordance with a second alternative, in the sixteenth sub-step (FIG. 18) comparatively narrow, deep trenches of a trench structure 71 are etched into functional layer 300 or second polysilicon layer 300, i.e. the trenches have an aspect ratio higher than 1, which may be higher than 2.5. In the seventeenth sub-step (FIG. 19) the trench structure is closed off with fourth sub-layer 74, in particular an oxide layer, i.e. filled with the material of the fourth sub-layer, etching openings 74′ of the fourth sub-layer being etched into fourth sub-layer 74; in the eighteenth sub-step (FIG. 20) the silicon material of functional layer 300 which is disposed between the oxide-filled trenches 74′ being etched out by isotropic silicon etching through etching openings 74′ of the fourth sub-layer; in a nineteenth sub-step (FIG. 21), fifth sub-layer 75, in particular an oxide layer, is deposited, etching openings 74′ of the fourth sub-layer being closed off. In a twentieth sub-step depicted in FIG. 22, a further contact region 76 is etched into the fourth and/or fifth sub-layer 74, 75. In a twenty-first sub-step depicted in FIG. 23, a closure layer 77 is deposited, closure layer 77 being in particular a third polysilicon layer 77. Optionally, in a twenty-second sub-step depicted in FIG. 24 a metal layer 72, in particular an aluminum layer 72, is deposited and patterned, a connecting arrangement 72 being formed from metal layer 72. In a twenty-third sub-step depicted in FIG. 25, a structure 77′ of the closure layer is etched into closure layer 77, structure 77′ of the closure layer encompassing in particular a plurality of etching conduits, the etching conduits each extending along a projection direction parallel to normal direction 103 at least partly or entirely through closure layer 77. The etching conduits of structure 77′ of the closure layer may have an aspect ratio higher than 1, particularly may be higher than 1.5, very particularly may be higher than 2.5. In particular, contact region 76 is electrically insulated from closure layer 77 by an etching conduit.

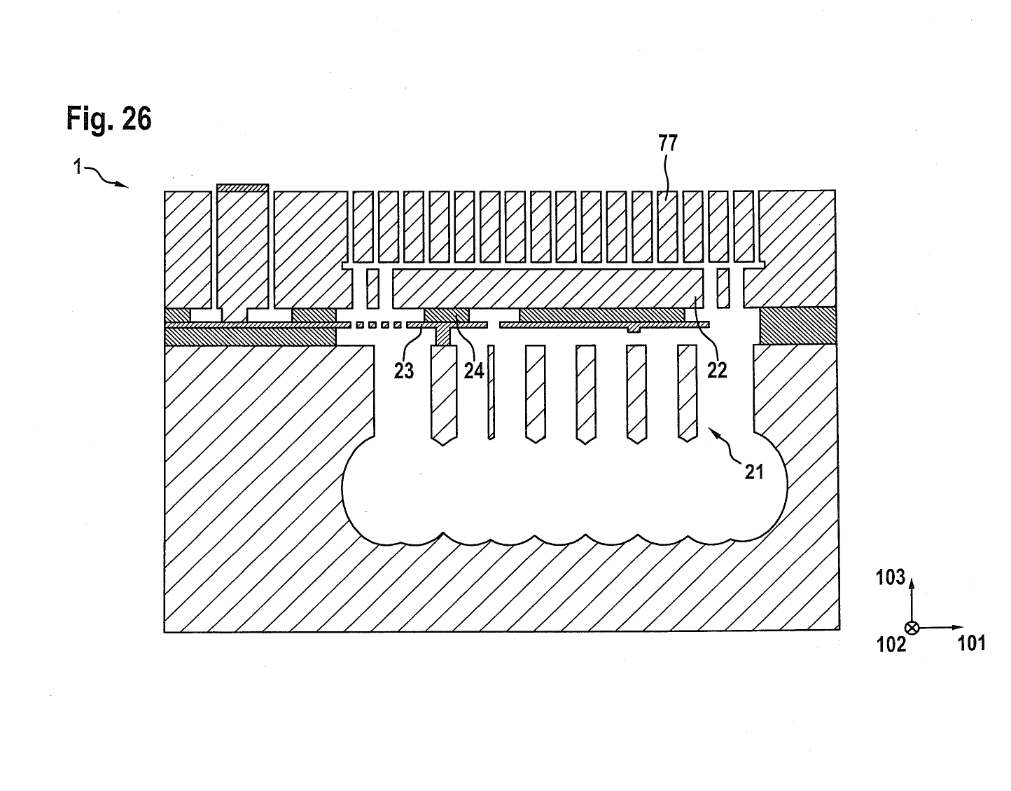

In a third manufacturing step a movable element 20 is constituted from first sub-element 21 and second sub-element 22, movable element 20 being attached by way of a spring arrangement assemblage 30 to substrate 10, movable element 20 being disposed in such a way that movable element 20 is deflectable out of a rest position into a deflection position. In a twenty-fourth sub-step depicted in FIG. 26, the MEMS structures are etched out of substrate 10, i.e. movable element 20 is disengaged, by way of a sacrificial layer etching method, in particular by way of a gas-phase etching method using hydrofluoric acid (HF). Etching conduits 77′ or etching trenches 71′ that correspond to one another, i.e. that at least partly or entirely overlap along a projection direction parallel to normal direction 103, may be generated in first and/or second functional plane 200, 200′.

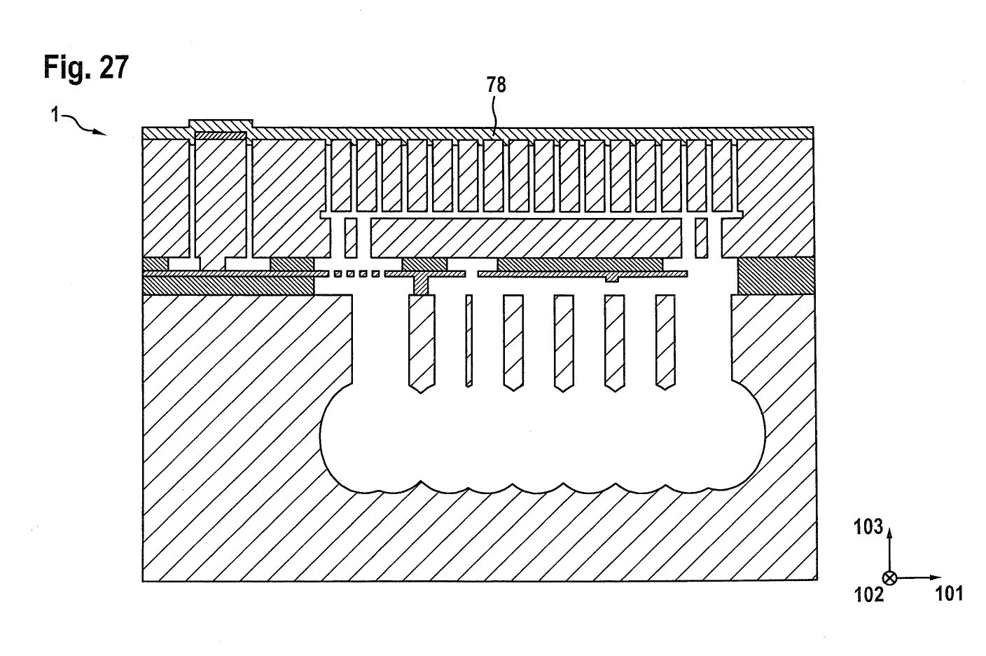

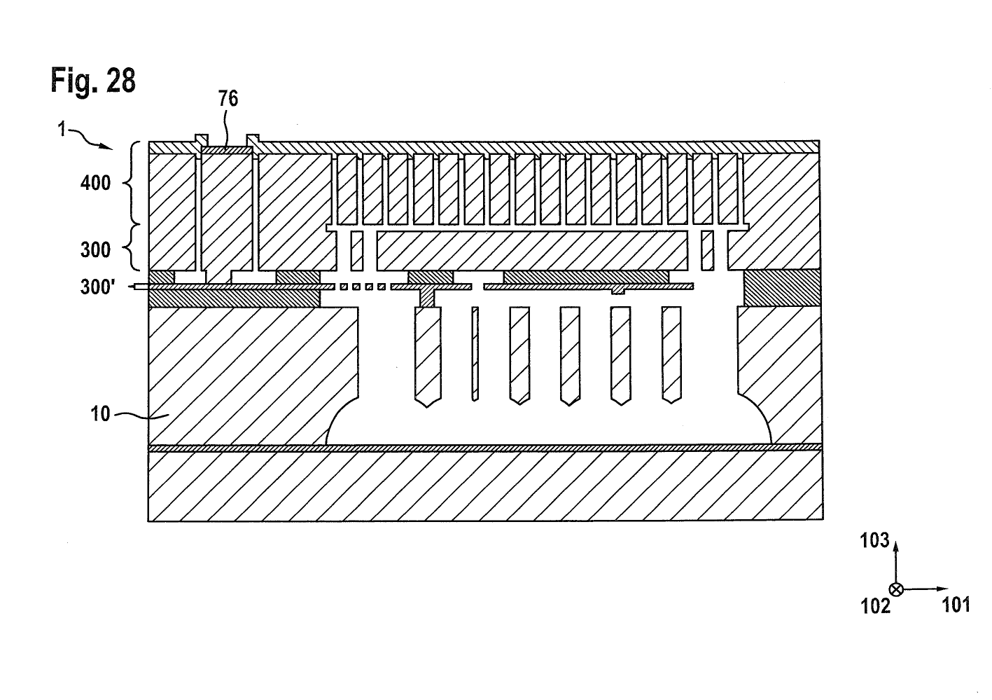

In a fourth manufacturing step, micromechanical component 1 is hermetically encapsulated by way of an encapsulating arrangement 40; in a twenty-fifth sub-step depicted in FIG. 27, encapsulating arrangement 40 is formed from an encapsulating layer 400 encompassing third polysilicon material 77 and sealing layer 78. Sealing layer 78 may be formed by oxide deposition of an oxide material. In a twenty-sixth sub-step depicted in FIG. 28, optionally contact region 76 is disengaged.

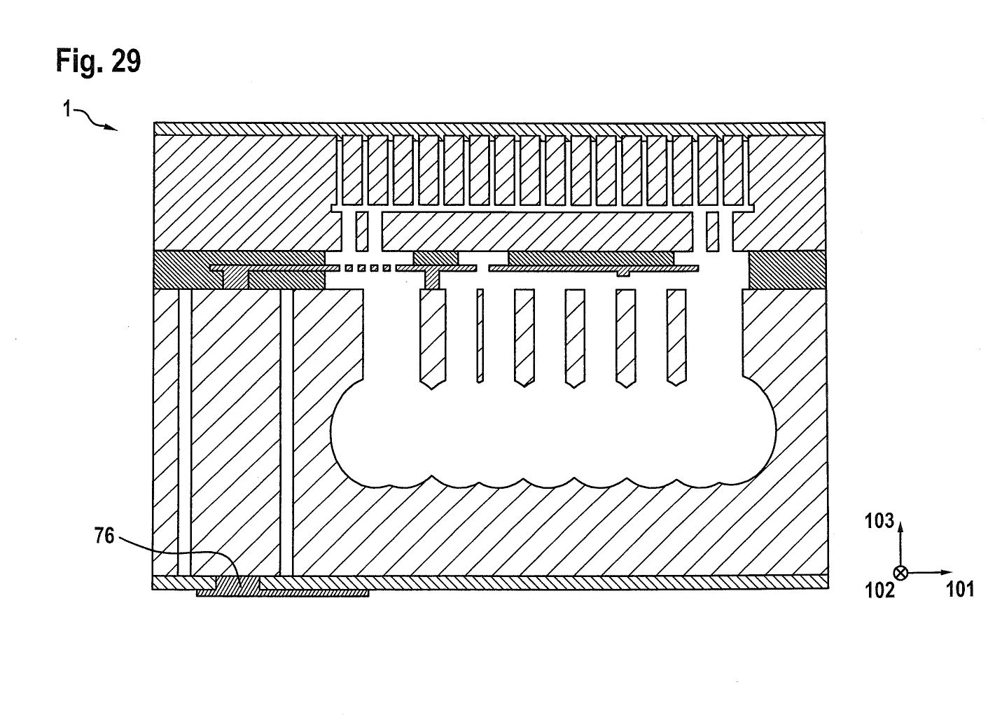

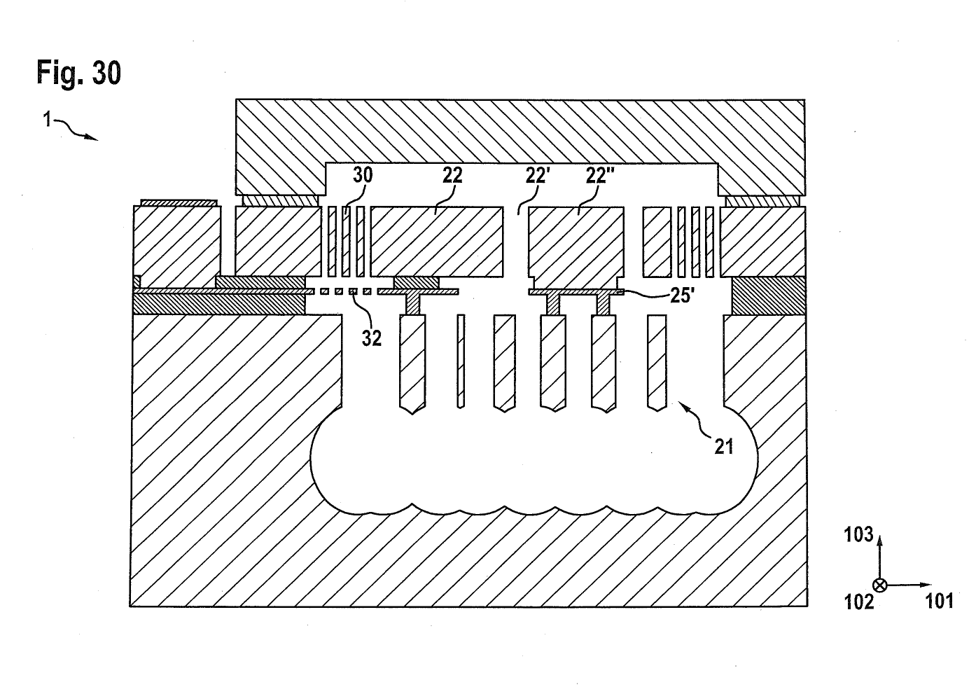

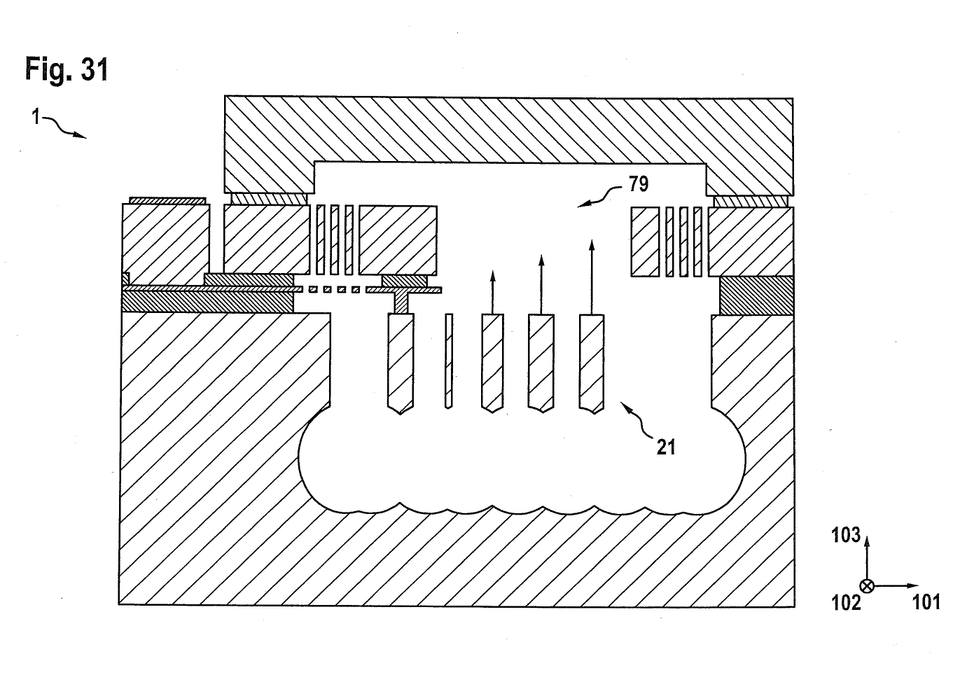

FIGS. 29 to 31 depict various embodiments of micromechanical component 1 of the present invention. The embodiment depicted in FIG. 29 corresponds substantially to the embodiments described in FIGS. 3 to 6 and 17 to 28, movable element 20 and contact region 76 here being disposed along normal direction 103 on opposite sides of substrate 10. The embodiment depicted in FIG. 30 corresponds substantially to the embodiments described in FIGS. 1, 2, and 3 to 16, second sub-element 22 and a further second sub-element 22″ here being formed out of functional layer 300 and each extending mainly along functional plane 200, second sub-element 22 and further second sub-element 22″ being spaced away from another by an opening 22′. The second sub-element may be connected to first sub-element 21, which may be electrically conductively, via a further connecting element 25′. In particular, the spring arrangement assemblage has a first spring arrangement 31 and a second spring arrangement 32, the first spring arrangement being formed out of functional layer 300 and second spring arrangement 32 out of further functional layer 300′. As a result, it is advantageously possible to constitute sub-structures of micromechanical component 1, for example movable element 20, stationary electrodes, and/or spring arrangement assemblage 30, in such a way that the sub-structures are disposed at/on both or exclusively one of the two functional layers 300, 300′, or extend mainly along functional plane 200 and further functional plane 300′. It is thereby advantageously possible to increase the mass and/or electrode area of movable element 20 in an efficient manner. The embodiment depicted in FIG. 31 corresponds substantially to the embodiments depicted in FIGS. 1, 2, 3 to 16, and 30, second sub-element 22 here having a cutout region 79, the cutout region extending entirely through second sub-element 22, i.e. extending along a projection direction parallel to normal direction 103 over the entire layer thickness 210 of functional layer 300. Alternatively or additionally, first sub-element 21 and/or third sub-element 23 also has a cutout region. It is thereby advantageously possible to enable for movable element 20, here in particular first sub-element 21, a comparatively large freedom of movement in normal direction 103, which is indicated by the arrows placed on first sub-element 21.

What is claimed is:

1. A micromechanical component, comprising:
a substrate having a main plane of extension;
a movable element;
a spring arrangement assemblage, the movable element being attached to the substrate by the spring arrangement assemblage, the movable element being deflectable out of a rest position into a deflection position;
wherein the movable element includes a first sub-element and a second sub-element connected to the first sub-element, the first sub-element extending mainly along the main plane of extension of the substrate,
wherein the second sub-element extends mainly along a functional plane, which is disposed substantially parallel to the main plane of extension of the substrate, the functional plane being spaced away from the main plane of extension.

2. The micromechanical component of claim 1, wherein the movable element includes a third sub-element connected to the second sub-element, the third sub-element extending mainly along a further functional plane, the further functional plane being disposed substantially parallel to the main plane of extension of the substrate, the further functional plane being spaced away from the functional plane and from the main plane of extension, the functional plane being disposed, along a normal direction substantially perpendicular to the main plane of extension, between the main plane of extension of the substrate and the further functional plane.

3. The micromechanical component of claim 1, wherein the first sub-element has a single-crystal silicon material, and wherein at least one of the second sub-element and the third sub-element having a polysilicon material.

4. The micromechanical component of claim 1, wherein the second sub-element has a layer thickness extending along a projection direction parallel to the normal direction, the third sub-element having a further layer thickness extending along the projection direction, the further layer thickness being greater than the layer thickness.

5. The micromechanical component of claim 1, wherein the movable element is connected to the substrate by the spring arrangement assemblage, in particular exclusively.

6. The micromechanical component of claim 1, wherein the spring arrangement assemblage includes at least two spring arrangement attaching the movable element to the substrate, one spring arrangement of the at least two spring arrangement extending mainly along at least one of the functional plane and the further functional plane.

7. The micromechanical component of claim 1, wherein the micromechanical component includes a connecting arrangement, and wherein at least one of the first sub-element, the second sub-element, and the third sub-element is electrically conductively connected to the connecting arrangement via the spring arrangement assemblage.

8. A method for manufacturing a micromechanical component, the method comprising:
furnishing, in a first manufacturing task, a substrate having a main plane of extension, a first sub-element extending mainly along the main plane of extension of the substrate being formed from the substrate material;
connecting, in a second manufacturing task, a second sub-element extending mainly along a functional plane to the first sub-element, the functional plane being disposed substantially parallel to the main plane of extension of the substrate, the functional plane being disposed spaced away from the main plane of extension; and
in a third manufacturing task, a movable element (20) is constituted from the first sub-element and the second sub-element, the movable element being attached by a spring arrangement assemblage to the substrate, the movable element being disposed so that the movable element is deflectable out of a rest position into a deflection position.

9. The method of claim 8, wherein in the second manufacturing task a third sub-element extending mainly along a further functional plane is connected to the second sub-element, the further functional plane being disposed substantially parallel to the main plane of extension of the substrate, the further functional plane being disposed spaced away from the main plane of extension of the substrate and from the functional plane, the functional plane being disposed, along a normal direction substantially perpendicular to the main plane of extension, between the main plane of extension of the substrate and the further functional plane, in the third manufacturing task the movable element being formed from the first, second, and third sub-elements.

10. The method of claim 8, wherein the movable element is connected to the substrate by the spring arrangement assemblage.

11. The method of claim 8, wherein in a fourth manufacturing task, the micromechanical component is hermetically encapsulated using an encapsulating arrangement, the encapsulating arrangement being made either from a polysilicon material and a sealing layer or from a wafer material.

12. The method of claim 8, wherein the movable element is connected to the substrate by the spring arrangement assemblage, via at least one of the second sub-element and the third sub-element.

13. The micromechanical component of claim 1, wherein the movable element is connected to the substrate by the spring arrangement assemblage, via at least one of the second sub-element and the third sub-element.
